(19) United States
(12) Patent Application Publication
(10) Pub. No.: US 2016/0204017 A1
(43) Pub. Date: Jul. 14, 2016

(54) Embrittlement device, pick-up system and method of picking up chips

(71) Applicant: Infineon Technologies Austria AG, Villach (AT)

(72) Inventors: Michael Roesner, Villach (AT); Chu Hua Goh, Malacca (MY); Markus Heinrici, Villach (AT); Joachim Hirschler, Villach (AT); Irina Mueller, Kuehnsdorf (AT)

(21) Appl. No.: 14/995,040

(22) Filed: Jan. 13, 2016

(30) Foreign Application Priority Data
Jan. 14, 2015 (DE) 10 2015 100 512.3

(51) Int. Cl. H01L 21/683; B25J 11/00; H01L 21/67

(52) U.S. Cl. CPC H01L 21/6836; H01L 21/67132; B25J 11/0095

(57) ABSTRACT

Various embodiments provide a method of picking up a chip from a carrier system, wherein the method comprises providing a carrier system comprising a plurality of chips comprising edge portions and being attached to a one surface of the carrier system by an adhesive layer; embrittling the adhesive layer selectively at the edge portions of the plurality of chips; and picking up at least one chip of the plurality of chips.

### TECHNICAL FIELD

Various embodiments relate to an embrittlement device, a pick-up system and a method of picking up chips.

### BACKGROUND

Typically, semiconductor chips are presented on a foil held in a frame, also known in the trade as a tape, for processing with a mounting apparatus. The semiconductor chips adhere to the foil. The frame with the foil is accommodated by a movable wafer table. The wafer table is shifted in cycles so that one semiconductor chip after the other is presented at a first location A and then the presented semiconductor chip is picked up by a chip gripper and placed at a second location B on a substrate. Removal of the presented semiconductor chip from the foil is supported by a chip ejector (known in the trade as a die ejector) arranged underneath the foil. In doing so, as a rule at least one needle arranged in the chip ejector supports detachment of the semiconductor chip from the foil.

### SUMMARY

Various embodiments provide a method of picking up a chip from a carrier system, wherein the method comprises providing a carrier system comprising a plurality of chips comprising edge portions and being attached to a one surface of the carrier system by an adhesive layer; embrittling the adhesive layer selectively at the edge portions of the plurality of chips; and picking up at least one chip of the plurality of chips.

Furthermore, various embodiments provide an embrittlement device for a pick-up system for picking up a chip from a carrier system, wherein the embrittlement device is configured to embrittle selectively an adhesive layer at edge portions of the chips attached to the carrier system by the adhesive layer.

Moreover, various embodiments provide a pick-up system for picking up a chip from a carrier system, wherein the pick-up system comprises a frame configured to accommodate a carrier system having attached thereon a plurality of chips; and an embrittlement device.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A and 1B schematically illustrate a carrier system according to an exemplary embodiment;

FIG. 2 schematically illustrates an embrittlement device according to an exemplary embodiment;

FIG. 3 schematically illustrates another embrittlement device according to another exemplary embodiment;

FIG. 4 schematically illustrates a detail of an embrittlement device according to an exemplary embodiment;

FIG. 5 schematically illustrates a pick-up system according to an exemplary embodiment; and

FIG. 6 shows a flowchart of a pick-up method according to an exemplary embodiment.

### DETAILED DESCRIPTION

In the following further exemplary embodiments of an embrittlement device, a pick-up system and a method of picking up a chip from a carrier system will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a method of selectively embrittling portions of an adhesive layer of a carrier system for chips, wherein the respective selected portions correspond to edge portions of the chips attached to the carrier system. The embrittlement may be performed by selectively applying energy, e.g. cooling energy or light energy, to the respective edge portions. For example, the embrittlement may be performed by an embrittlement device which is configured to embrittle selectively an adhesive layer at edge portions of the chips attached to the carrier system by the adhesive layer. Optionally additional parts of the chip backside may be embrittled as well which are not connected to the edges or edge portions.

It should be noted that the term “selectively” may particularly denote that while a basic embrittling may be performed over or across the whole carrier system, an additional embrittlement is performed to the respective portions which are selectively embrittled. This may be performed by providing an additional amount of energy, e.g. light or cooling, to the respective portions. It should be noted that of course the embrittlement of the adhesive layer beneath the edge portions of the individual chips (of the plurality of chips) may be performed subsequently or in a kind of batch process, i.e. together in a single embrittling step.

In particular, it should be noted that specifically the embrittlement is performed at the edge portions of the chips. Thus, it has to be distinguished from an overall embrittlement of the whole adhesive layer. By embrittling especially the edge or boundary portions or regions of a chip attached or fixed to the carrier system, it may be possible that the pick-up action is eased and simplified. In particular, the edge portions of a chip may be difficult to lift off the carrier system, like a foil, since in case of thin chips the chips may rather bend or flex and still stick to the foil.

In particular, it may not be necessary any more to ensure that the carrier system and/or chip may not bend. Thus, it may not be necessary anymore that in case of thin wafers additional copper layers are attached to the wafer just for ensuring a necessary rigidity. Since the adhesion of the chip may be particularly weakened at the edge portions, the danger of bending may be substantially reduced even for thin wafers or chips and it may not be necessary to use such additional rigidity layers anymore so that the mismatch of the coefficient of temperature expansion (CTE) between the chip and the additional rigidity layer may be avoided increasing the durability of the thin chips. In particular, CTE mismatch, which typically results in significant chip bow during reflow process at die attach (leading to solder voids and chip tilt and resulting in poor die bond quality), may be avoidable when performing a selective embrittlement step according to an exemplary embodiment. Furthermore, it may be possible to use common needles, like used in so-called pepper-pots, to facilitate pick-up even thin chips having a chip thickness of well below 500 micrometer by common suction collets, for example. For example, total chip thicknesses of below 100 micrometer, preferably between 5 micrometer and 75 micrometer, e.g. between 10 micrometer and 50 micrometer, e.g. about 35 micrometer or even below 15 micrometer, may be easily handled.

Thus, by performing a method specifically embrittling the portions of an adhesive layer corresponding to edge portions of the attached chips it may be possible to provide a less complex process, since the rest of the embrittlement device or system (e.g. the needles, pepper-pots and collets) may not have to be adapted for thin chips and/or different chips (varying of size and/or thickness, for example). In particular, an indentation free pick-up of ultra-thin chips (e.g. having a thickness of below 35 micrometer) may be enabled, by performing a local (additional) embrittlement of the adhesive or glue layer around and under the chip edges or its periphery. Due to the local embrittlement a metal burr, often used in the known techniques, may no longer act as a barb, due to the local embrittlement.

In the following exemplary embodiments of the pick-up method are described. However, the features and elements described with respect to these embodiments can be combined with exemplary embodiments of the embrittlement device and the pick-up system.

According to an exemplary embodiment of the pick-up method the embrittling is performed by UV-light.

In particular, the UV-light may be supplied by a UV laser or by a UV lamp.

According to an exemplary embodiment of the pick-up method the UV light has a wavelength configured to pass through the carrier system.

In particular, the laser light may be guided onto the carrier system, e.g. a foil or glass (plexiglass or acrylic glass, for example) carrier, from below. That is, the layer light may be guided onto a further surface of the carrier system being opposite to the one surface (the chips are attached to). The use of such a wavelength for which the carrier system is transparent may provide for the advantage that the overall stability of the carrier system may not be reduced due to the used light. Thus, it may be possible that specifically the material of the adhesive layer may be embrittled and the adhesion of the chips to the carrier system may thus be efficiently reduced.

According to an exemplary embodiment of the pick-up method the embrittling is performed by applying cryogenic energy.

The term “applying cryogenic energy” may particular denote the applying of a (cooling) medium able to provide for a cooling action. In particular, the cryogenic energy may be provided by a cryogenic fluid, like nitrogen or air. For example, the cryogenic energy may be provided by guiding cool air or even liquid air to the backside (the side to which the chips are not attached to) of the carrier system. The use of such cryogenic energy, i.e. cooling or freezing, may be a suitable way to selectively embrittle the adhesive layer used to attach the chips to the carrier system, e.g. a foil or glass carrier.

According to an exemplary embodiment of the pick-up method the cryogenic energy is applied by guiding a cooling fluid selectively to the edge portions.

According to an exemplary embodiment of the pick-up method the carrier system is a foil and the method further comprises straightening the foil during picking up the at least one chip.

By straightening the foil during the picking up process or step it may be possible to ease the detaching or picking up of the chips. In particular, the straightening may be accomplished by a vacuum suction, e.g. by a vacuum pump or vacuum line arranged below the foil.

According to an exemplary embodiment of the pick-up method the carrier system is a foil and the method further comprises applying an additional force on the foil from a second surface of the foil, wherein the second surface is opposite to the one surface.

That is, the force may be exercised or applied to the foil from below or in other words from the side or surface of the foil which is opposite to the one surface (i.e. the surface the plurality of chips is arranged on). The applying of a force additional to the force applied by a picking up tool, e.g. a suction needle or (vacuum) pick-up collet, may enable to reduce the chances of damages, breaks or flection. For example, the additional force may be applied by needles pressing onto the carrier system (foil) from below.

According to an exemplary embodiment of the pick-up method the force is applied by a pulse of compressed gas.

In particular, the pulse of compressed gas may be a short pulse, e.g. may have a duration in the range between 1 millisecond and several seconds like 5 seconds for example, in particular about 20 milliseconds. Such a short pulse may be used to either ease a detaching of the chip by using a common (vacuum) collet from above or even to avoid the necessity of a vacuum collet for detaching. In particular, in case the gas pulse is sufficient to detach the chip from the carrier system, a vacuum collet may only be necessary to pick-up the chips but not detach the chips leading to the fact that the underpressure (or force) applied by the collet may be reducible possible reducing the chances of bending or flexing. Possible gases for the pulse of compressed gas may be air or N₂.

In the following exemplary embodiments of the embrittlement device are described. However, the features and elements described with respect to these embodiments can be combined with exemplary embodiments of the method of picking up a chip from a carrier system and the pick-up system.

According to an exemplary embodiment the embrittlement device comprises a cooling source configured to selectively embrittle the adhesive layer.

In particular, the (selective) use of a cooling or cooled media may be a suitable method for selectively embrittling an adhesive layer.

According to an exemplary embodiment the embrittlement device comprises a UV light source configured to selectively embrittle the adhesive layer.

In particular, the light source may be a laser light source. Preferably, the light may have a wavelength in the ultraviolet region, e.g. between 150 nm and 400 nm.

According to an exemplary embodiment the embrittlement device further comprises a mask, configured to expose selectively the edge portions.

For example, the mask may comprise transparent or void portions transparent for light of a light source while other portions may be opaque for the light. In particular, the transparent portions may match the edge portions of the chips. Alternatively, the mask may comprise portions having a relatively high thermal conductivity while other portions may exhibit a relatively low thermal conductivity. Such a mask may be advantageously used in case the embrittlement is performed by a cooling instead of light. However, the selectivity of the embrittlement may also be enabled by providing a guiding system for light and/or cooling, e.g. by (flexible) light guiding fiber(s) in case of light or (thin) fluid line(s) in case of applying cryogenic energy (cooling fluid).

According to an exemplary embodiment of the embrittlement device the UV light source further comprises a light guiding system configured to guide the light of the UV light source

In particular, the light guiding system may comprise or may consist of light guiding fibers. For example, the light guiding fibers may be flexible. Thus, it may be possible to provide a flexible light guiding mechanism which may be used in an efficient way for different kinds of chips, i.e. chips having different shapes, forms or sizes.

According to an exemplary embodiment the embrittlement device further comprises at least one lens being part of the light guiding system.

In particular, the at least one lens may be formed at an end of a light guiding fiber. In case the light guiding system comprises a plurality of light guiding fibers each light guiding fiber may comprise a lens at an end thereof. For example, the lenses may be configured to modify a light beam outputted by the light guiding fiber, e.g. focusing, shaping, collimating. Thus, it may be possible to provide a high flexible light guiding system.

By providing a lens or a plurality of lenses it may be possible that a flexible light guiding system may be provided. Thus, it may be possible that by a simple alteration or modifying of the light guiding system or optical system a geometry and/or size of the light (laser) beam may be modified. Therefore, it may be possible that it is not necessary to use different equipment (e.g. so-called pepper-pots or needles) for different chip technologies. It may also be possible to avoid the use of the needles (pepper pot) from the backside at all, therefore no or at least reduced indentations may be formed during the pick-up process in the chip surface.

In the following exemplary embodiments of the pick-up system are described. However, the features and elements described with respect to these embodiments can be combined with exemplary embodiments of the method of picking up a chip from a carrier system and the embrittlement device.

According to an exemplary embodiment the pick-up system further comprises a pick-up collet configured to pick-up a chip.

In particular, the pick-up collet may be a vacuum pick-up collet configured to suck up the chips to be detached or picked up from the carrier system.

According to an exemplary embodiment the pick-up system further comprises a gas guiding system configured to guide an gas pulse on a backside of the carrier system.

In particular, the gas guiding system may comprise a gas pump and/or a (micro) valve and/or fluid line(s). Such a gas guiding system may be adapted to guide a short gas pulse to the backside of the carrier system. Thus, it may be possible to detach or at least reduce the adhesion of the chip to the carrier system only by the gas pulse so that no additional needles may be necessary to detach the chips. Therefore, it may be possible that no indentations are formed on the surface of the chips during the pick-up process. It should be noted that the gas guiding system may of course be used together with a needle system in which case the mechanical force imposed by the needles may at least be reduced thus also reducing the probability of the formation of indentations.

In the following specific embodiments of the embrittlement device, the pick-up system and the method of picking up a chip from a carrier system will be described in more detail with respect to the figures.

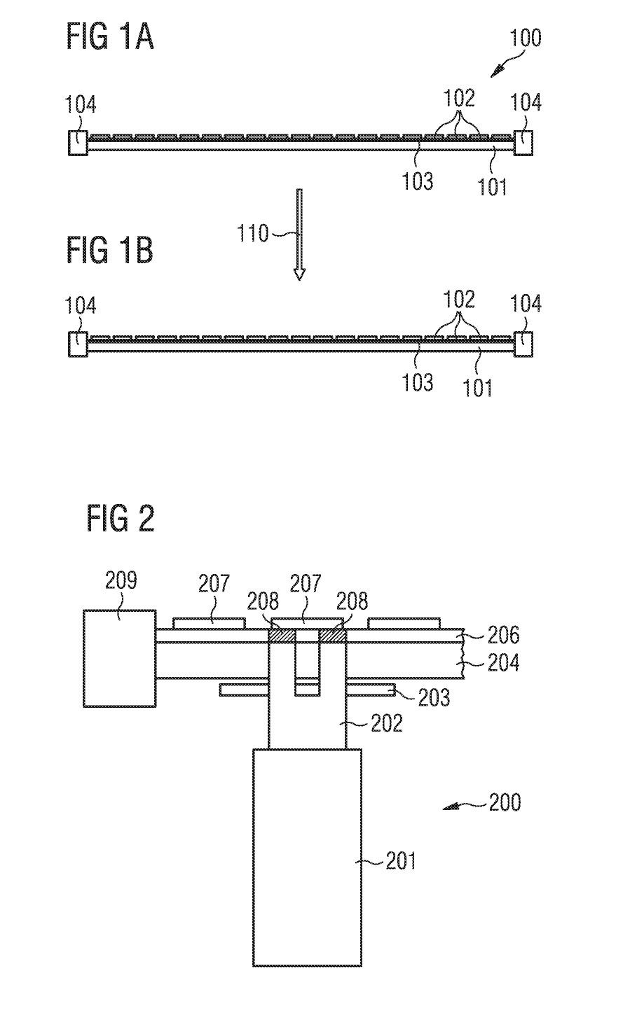

FIGS. 1A and 1B schematically illustrate a carrier system according to an exemplary embodiment. In particular, FIG. 1 shows a carrier system 100 formed by a foil or glass layer 101 on which a plurality of chips 102 is fixed or glued by an adhesive or glue layer 103. A possible adhesive may comprise or may consists of polyimide, for example. The carrier system 100 is supported or hold by a (metal) frame 104. Preferably, the foil or glass layer 101 is of a material transparent for UV light, in case the adhesive layer is embrittled by UV light. However, it may be formed by an opaque material in case the adhesive layer is afterwards embrittled by a cooling fluid.

Preferably, in a first step the whole adhesive layer 103 may be exposed to an embrittlement step, which is schematically indicated by arrow 110. However, according to exemplary embodiments afterwards the adhesive or glue layer 103 is additionally selectively exposed to an embrittlement step, only embrittling the adhesive layer in portions corresponding to an edge portion of the attached chips, which will be explained in more detail with reference to the following figures.

FIG. 2 schematically illustrates an embrittlement device 200 according to an exemplary embodiment. In particular, the embrittlement device 200 comprises a UV light source 201 like a laser or UV lamp. The UV light source puts out a light beam 202 which is formed, modified or patterned by a mask schematically illustrated as 203 in FIG. 2. The patterned light beam passes then through a foil or glass layer 204 of a carrier system 205 and illuminates an adhesive layer 206 used for attaching a plurality of chips 207.

Due to the patterning of the UV light beam only specific portions 208 of the glue layer 206 are exposed to the UV light. Thus, only the exposed regions of the adhesive layer corresponding to the edge portions or regions of chips are embrittled by the UV light. Furthermore, a frame 209 is schematically indicated in FIG. 2 as well. According to the embodiment of FIG. 2 the light source is arranged directly below the carrier system or at the backside of the same. It should be noted that the “backside” of the carrier system is formed by the side to which no chips are attached to.

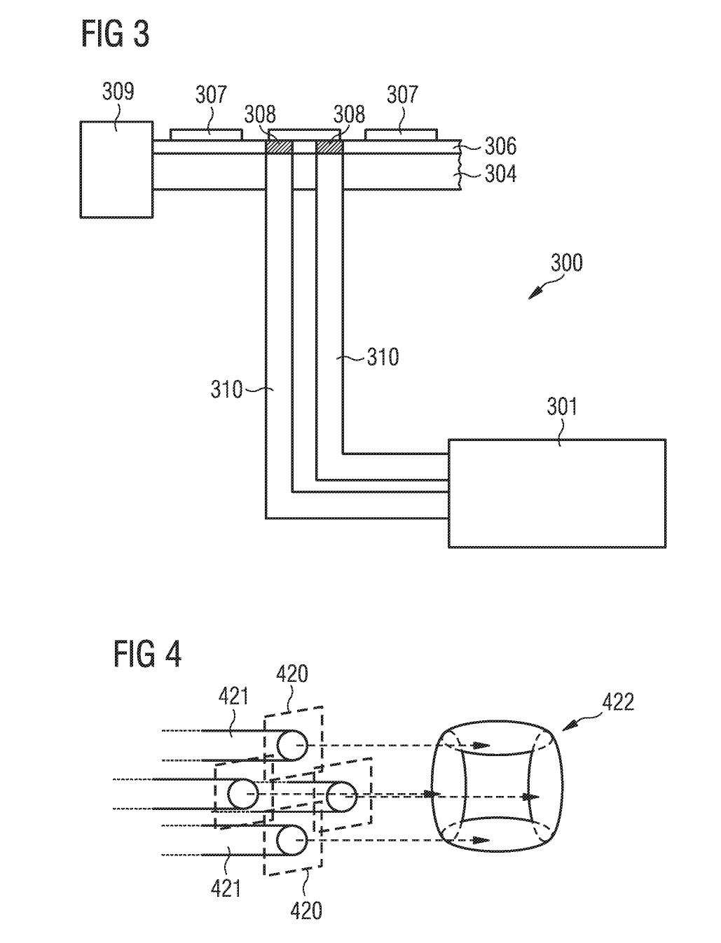

FIG. 3 schematically illustrates another embrittlement device 300 according to another exemplary embodiment. In particular, the embrittlement system 300 comprises a UV light source 301 like a laser or UV lamp. The UV light source puts out a light beam 302. However, in difference to the embodiment shown in FIG. 2 the light source is coupled to optical or light guiding fibers 310. Thus, the UV light is transported through the optical fiber (e.g. flexible fiberglass cables), which may be attached to e.g. a so-called pepper-pot. Thus, no mask is necessary since already the optical fibers ensure an exposing pattern. However, an additional mask may be provided as well. Preferably, the optical fibers are combined with a collimator system and/or lenses forming or modifying the UV light pattern as well. The patterned light beam passes then through a foil or glass layer 304 of a carrier system 305 and illuminates an adhesive layer 306 used for attaching a plurality of chips 307.

Due to the patterning of the UV light beam only specific portions 308 of the glue layer 306 are exposed to the UV light. Thus, only the exposed regions corresponding to the edge regions of chips are embrittled by the UV light. Furthermore, a frame 309 is schematically indicated in FIG. 3 as well. Due to the provision of flexible optical fibers 310 the UV light source may be arbitrarily arranged and may particularly be mechanically decoupled from the frame and the carrier system. It may as well be mechanically decoupled from further elements of a pick-up system or tool.

FIG. 4 schematically illustrates a detail of an embrittlement device according to an exemplary embodiment. In particular, FIG. 4 schematically illustrates that lenses 420 provided at an emitting or output end of optical fibers 421. For example, the output ends itself may form the lenses or additional (separate) lenses may be arranged in the light path. Depending on the geometry of the lenses a light pattern may be formed. For example, cylindrical lenses may be used to provide elliptical output pattern of the optical fibers. Thus, it may be possible to expose all edge portions of a chip (or the adhesive layer below the chip) of a rectangular chip by four optical fibers.

FIG. 5 schematically illustrates a pick-up system according to an exemplary embodiment. In particular, the pick-ups system 500 comprises a gas guiding system 530 comprising a (pressure) portion 531 to provide a gas pulse impinging on a backside of a foil 504 (schematically indicated by arrow 532), while another (suction) portion 533 of the gas guiding system functions as a suction unit by providing a vacuum or under-pressure to the foil (indicated by arrows 534). While the gas pulse of the pressure portion 531 may facilitate an easy lifting or pick-up of chips the (suction) portion 533 provides for a straightening of the foil 504.

Furthermore, FIG. 5 illustrates a carrier system comprising the foil 504, an adhesive layer 506 on which a plurality of chips 507 are arranged or fixed. The carrier system is supported by a (metal) frame 509. In addition the pick-up system 500 comprises a (suction) collet 535 used for lifting or pick-up of the chips. Before the chips are picked-up by the collet the adhesive layer 506 was already selectively embrittled in regions 508 corresponding to edge portions of the chips.

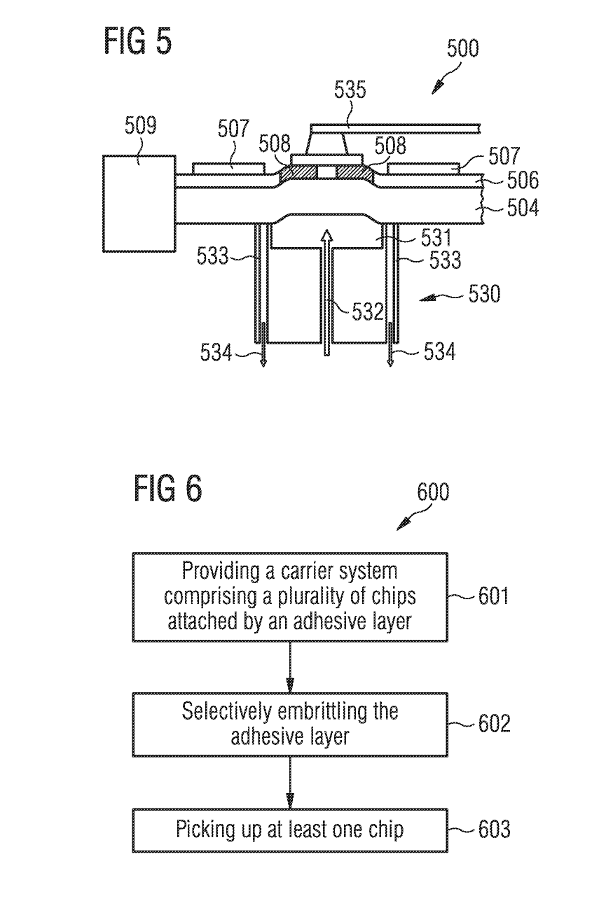

FIG. 6 shows a flowchart of a pick-up method according to an exemplary embodiment. In particular, the method 600 comprises providing a carrier system (step 601) comprising a plurality of chips comprising edge portions and being attached to a one surface of the carrier system by an adhesive layer. Afterwards the adhesive layer is selectively embrittled at the edge portions of the plurality of chips (step 602). For performing the selective embrittlement step a UV light source or a source of cryogenic energy may be placed and aligned below the carrier system. For providing the selective embrittlement pattern a mask may be located between the energy source (UV light or cryogenic energy). Then at least one chip of the plurality of chips is picked up (step 603), e.g. by suction needles or a suction collet.

Summarizing, an embrittling step selectively embrittling only specific regions of the adhesive layer, in particular the regions corresponding to the edge portions of the attached chips, may provide for some advantages. For example, it may be possible to process very thin chips, e.g. below 35 micrometer, without providing an additional rigidity layer, e.g. made of copper. Due to the possible omitting of such an additional rigidity layer, it may be possible to avoid a CTE mismatch between the rigidity layer and the chip itself. Thus, chip bow during reflow process at die attach may be avoided so that the resulting solder voids and chip tilt, resulting in poor die bond quality, may be avoided as well. In particular, an indentation free process (or at least one having smaller/fewer indentations) even for ultra-thin chips may be enabled due to local embrittlement of the adhesive layer below and close to the chip edges.

Such an embrittlement may be achieved by local energy dose deposition through a carrier system, e.g. dicing foil or a glass carrier, into the adhesive layer. In case a metal burr is used in the process this metal burr may no longer act like a barb because the adhesive or glue layer along the barb is embrittled. This may permit a release of ultra-thin chip edges from the adhesive layer without mechanical bending of the chip and may enable a subsequent pick-up either by vacuum sucking of the chip using the conventional pick-up collet or by additional gas pressure pulse, e.g. from a micro valve located below. Preferably, the foil below the chip may be straightened by vacuum suction during pick up.

It should also be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of picking up a chip from a carrier system, the method comprising:
providing a carrier system comprising a plurality of chips comprising edge portions and being attached to one surface of the carrier system by an adhesive layer;
embrittling the adhesive layer selectively at the edge portions of the plurality of chips; and
picking up at least one chip of the plurality of chips.

2. The method according to claim 1, wherein the embrittling is performed by UV-light.

3. The method according to claim 2, wherein the UV light has a wavelength configured to pass through the carrier system.

4. The method according to claim 1, wherein the embrittling is performed by applying cryogenic energy.

5. The method according to claim 4, wherein the cryogenic energy is applied by guiding a cooling fluid selectively to the edge portions.

6. The method according to claim 1, wherein the carrier system is a foil and wherein the method further comprises straightening the foil during picking up the at least one chip.

7. The method according to claim 1, wherein the carrier system is a foil and wherein the method further comprises applying an additional force on the foil from a second surface of the foil, wherein the second surface is opposite to the one surface.

8. The method according to claim 7, wherein the force is applied by a pulse of compressed gas.

9. Embrittlement device for a pick-up system for picking up a chip from a carrier system, wherein the embrittlement device is configured to embrittle selectively an adhesive layer at edge portions of the chips attached to the carrier system by the adhesive layer.

10. The embrittlement device according to claim 9, wherein the embrittlement device comprises a cooling source configured to selectively embrittle the adhesive layer.

11. Embrittlement device according to claim 9, wherein the embrittlement device comprises a UV light source configured to selectively embrittle the adhesive layer.

12. Embrittlement device according to claim 9, wherein the embrittlement device further comprises a mask, configured to expose selectively the edge portions.

13. Embrittlement device according to claim 11, wherein the UV light source further comprises a light guiding system configured to guide the light of the UV light source

14. The embrittlement device according to claim 13, further comprising at least one lens being part of the light guiding system.

15. A pick-up system for picking up a chip from a carrier system, the pick-up system comprising:
a frame configured to accommodate a carrier system having attached thereon a plurality of chips; and
an embrittlement device according to claim 9.

16. The pick-up system according to claim 15, further comprising a pick-up collet configured to pick-up a chip.

17. The pick-up system according to claim 15, further comprising a gas guiding system configured to guide a gas pulse on a backside of the carrier system.
